(19) United States
(12) Patent Application Publication
(10) Pub. No.: US 2025/0237248 A1
(43) Pub. Date: Jul. 24, 2025

(54) FASTENERS FOR FASTENING CIRCUIT CARDS

(71) Applicant: Steering Solutions IP Holding Corporation, Saginaw, MI (US)

(72) Inventors: Joshua Dornseifer, Saginaw, MI (US); Michael J. Srda, Clio, MI (US)

(21) Appl. No.: 18/416,058

(22) Filed: Jan. 18, 2024

(51) Int. Cl. F16B 5/06; H05K 7/14

(52) U.S. Cl. CPC F16B 5/06; H05K 7/1417

(57) ABSTRACT

A fastener including: a head; a first pin extending from the head along a longitudinal axis, the first pin including a surface feature configured to engage a first circuit card assembly; and a second pin extending from the head a direction opposite the first pin, the second pin including a stopper wall and a plurality of deflectable arms configured to deflect toward the longitudinal axis when inserted into a second circuit card assembly to couple the second pin to the second circuit card assembly. The stopper wall extends from at least one of the plurality of deflectable arms away from the longitudinal axis, and is configured to contact the second circuit card assembly when the plurality of deflectable arms are coupled to the second circuit card assembly.

### TECHNICAL FIELD

The present specification generally relates to fasteners and, more specifically, fasteners for fastening circuit card assemblies to metal castings.

### BACKGROUND

Screws are used in various manufacturing processes to attach one component to another. Manufacturing using screws requires controlling of torque values when fastening the components together. Controlling torque can be difficult to replicate and increases the time required for manufacture. Additionally, overtightening of the screws can result in damage to the components being attached together. Accordingly, a need exists for alternative fasteners for attaching two components together.

### SUMMARY

In one embodiment, a fastener for fastening circuit card assemblies, the fastener includes: a head having a first radius; a first pin having a second radius smaller than the first radius, the first pin extends from the head along a longitudinal axis, the first pin including an outer surface circumferentially surrounding the longitudinal axis and a surface feature extending on the outer surface between the head and a tip of the pin, the surface feature is configured to engage a first circuit card assembly; and a second pin extending from the head along the longitudinal axis in a direction opposite the first pin, the second pin including a stopper wall and a plurality of deflectable arms configured to deflect toward the longitudinal axis when inserted into a second circuit card assembly to couple the second pin to the second circuit card assembly, and the stopper wall extends from at least one of the plurality of deflectable arms away from the longitudinal axis, the stopper wall is configured to contact the second circuit card assembly when the plurality of deflectable arms are coupled to the second circuit card assembly.

In another embodiment, a fastener for fastening circuit card assemblies, the fastener including: a head having a first radius; a first pin having a second radius smaller than the first radius, the first pin extends from the head along a longitudinal axis, the first pin including an outer surface circumferentially surrounding the longitudinal axis and a surface feature extending on the outer surface from the head toward a tip of the pin, the surface feature includes at least one of: a plurality of barbs, a helical knurl, and a plurality of threads, and the surface feature is configured to engage a first circuit card assembly; and a second pin extending from the head along the longitudinal axis in a direction opposite the first pin, the second pin including a plurality of deflectable arms configured to deflect toward the longitudinal axis when inserted into a second circuit card assembly to couple the second pin to the second circuit card assembly.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 depicts a perspective view of a fastener coupling a pair of circuit card assemblies and a circuit card housing, according to one or more embodiments shown and described herein;

FIG. 2A depicts a perspective view of an example fastener, according to one or more embodiments shown and described herein;

FIG. 2B depicts a cross-sectional side view of an example fastener being inserted into a circuit card housing, according to one or more embodiments shown and described herein;

FIG. 3 depicts a perspective view of another example fastener, according to one or more embodiments shown and described herein; and

FIG. 4 depicts a perspective view of yet another example fastener, according to one or more embodiments shown and described herein.

### DETAILED DESCRIPTION

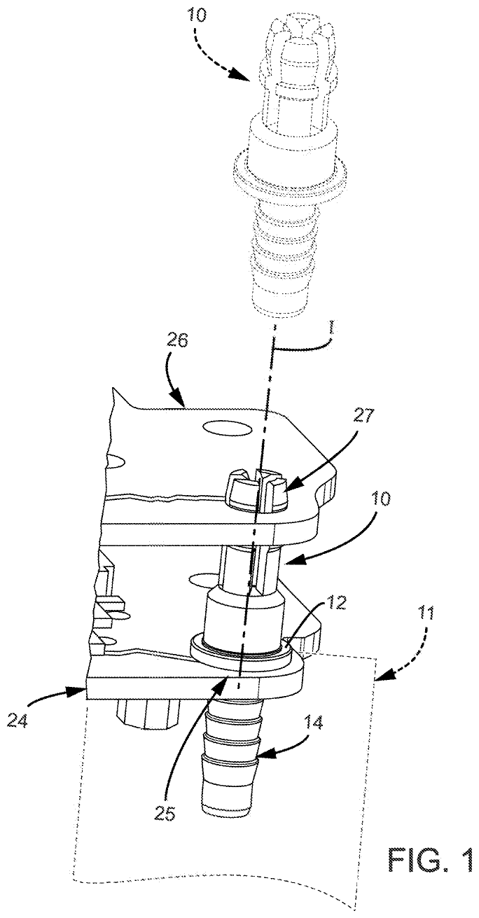

Referring initially to FIG. 1, a pair of circuit card assemblies being fastened together is depicted. A first circuit card assembly 24 is fastened to a second circuit card assembly 26 by a fastener 10 through a press-fit engagement. The first circuit card assembly 24 includes a first attachment opening 25 and the second circuit card assembly 26 includes a second attachment opening 27 each for receiving a portion of the fastener 10. The first attachment opening 25 may have an opening radius that is less than a radius of at least a portion of pin 14 of the fastener 10. Alternatively, the first attachment opening 25 may have an opening radius that is greater than a radius of the pin 14, where the first circuit card assembly 24 is attached to a circuit card housing 11 by being positioned between the head 12 of the fastener 10 and the circuit card housing 11. Each circuit card assembly may include a printed circuit board (PCB) and electronic components such as capacitors, transistors, inductors, or the like on the PCB. The pair of circuit card assemblies may be attached to the circuit card housing 11 by insertion of the pin of the fastener 10 into an opening in the circuit card housing 11. The pair of circuit card assemblies may be a power card for metering power to a device, and a control card for controlling operation of the device. The circuit card housing 11 may be formed of any operable material, such as plastic or metal, where the circuit card housing 11 may be a metal casting. In some embodiments, the circuit card housing 11 may be a housing for an electric motor, such as an electric vehicle motor. In further embodiments, the circuit card housing 11 may be a plastic housing, such as for use with a steering column, for use with smaller circuit card assemblies than used with metal castings. The preceding examples are merely examples and are not limiting of the component materials or applications of use.

The fastener 10 extends into the first attachment opening 25 of the first circuit card assembly 24, the second attachment opening 27 of the second circuit card assembly 26, and the opening of the circuit card housing 11 to couple the circuit card assemblies to the circuit card housing 11, where the fastener 10 completes the ground path between the pair of circuit card assemblies and the circuit card housing 11, thereby grounding the circuit card assemblies. As shown in phantom, the fastener 10 may be inserted into the circuit card assemblies and the circuit card housing 11 along an insertion axis I that extends through a center of the first attachment opening 25, the second attachment opening 27, and the opening in the circuit card housing 11.

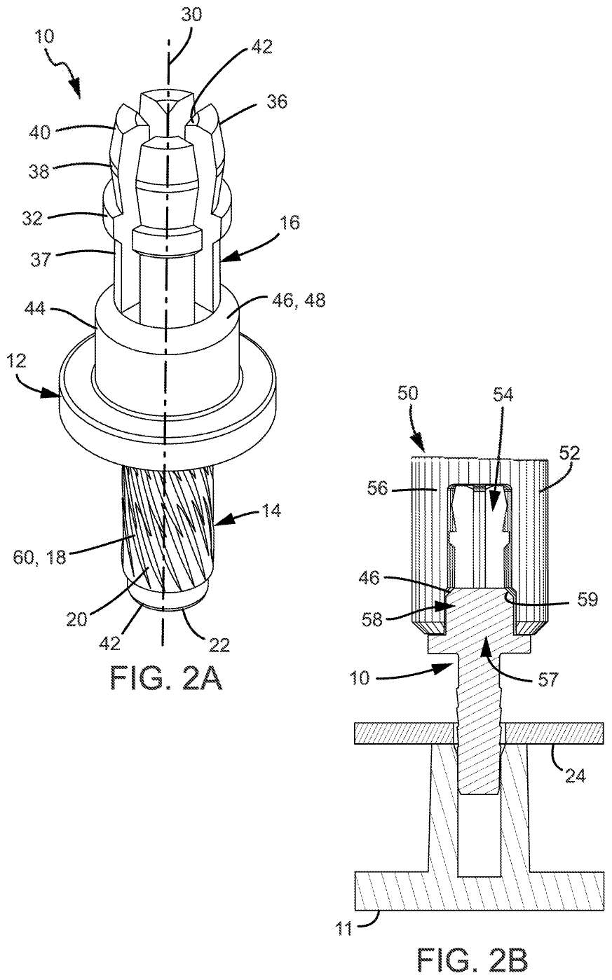

Referring now to FIG. 2A, a first embodiment of the fastener 10 of FIG. 1 is depicted. The fastener 10 includes a head 12, a first pin 14 extending from the head 12 along a longitudinal axis 30, and a second pin 16 extending from the head 12 along the longitudinal axis 30 in a direction opposite the first pin 14. The head 12 has a first radius, the first pin 14 has a second radius that is less than the first radius, and the second pin 16 has a third radius that is less than the first radius. The first pin 14 includes an outer surface 18 circumferentially surrounding the longitudinal axis 30 and a surface feature 20 extending on the outer surface 18 from the head 12 toward a tip 22 of the pin 14. The surface feature 20 may be at least one of a plurality of barbs, a helical knurl, and a plurality of threads to be configured to engage the first circuit card assembly 24 and the circuit card housing 11. The depicted fastener 10 of FIG. 2A includes the helical knurl 60. The helical knurl 60 includes a plurality of knurls extending from the head 12 to the tip 22 of the first pin 12, where the plurality of knurls form a helix, and each of the plurality of knurls at least partially circumferentially surrounds the longitudinal axis 30. When the fastener 10 is inserted into the attachment openings, the helical knurl 60 may rotate the fastener 10 as the fastener 10 moves into the attachment openings. The helical knurl 60 similarly causes the fastener 10 to rotate when the fastener 10 is being removed from the attachment openings. However, a tool, such as a claw head hammer, provides a normal force against the head 12 of the fastener 10 during removal, thereby resisting rotation of the fastener 10 and increasing the force required for removing the fastener 10 when compared to insertion. The helical knurl 60 may include any operable number of knurls, such as 1, 20, between 1 and 20, or more than 20 knurls. Each knurl may be disposed at an angle relative to the longitudinal axis 30 when viewed in a side view. The angle may be between 10° and 80°, more specifically, between 25° and 40° including endpoints in some embodiments.

The fastener 10 may include a chamfer 42 at the tip 22 of the first pin 14 that has an angle between 25° and 40° relative to the longitudinal axis 30. The fastener 10 may further include a length of the pin 14 that does not include the surface feature 20 positioned between the surface feature 20 and a tip 22 of the pin 14, where the length of the pin 14 without the surface feature 20 extends from the surface feature 20 to the chamfer 42. The fastener 10 may include a zinc coating (or other coating that permits grounding) for preventing corrosion.

The second pin 16 of the fastener 10 may include a stopper wall 32, a plurality of deflectable arms 36, and a pedestal 44 that the deflectable arms 36 extend from. The plurality of deflectable arms 36 may be configured to deflect toward the longitudinal axis 30 when inserted into the second circuit card assembly 26 to couple the second pin 16 to the second circuit card assembly 26 through a press-fit engagement. The stopper wall 32 may extend from at least one of the plurality of deflectable arms 36, and may extend from each of the deflectable arms 36 away from the longitudinal axis 30 to radially circumscribe the longitudinal axis 30. The stopper wall 32 is configured to contact the second circuit card assembly 26 when the plurality of deflectable arms 36 are coupled to the second circuit card assembly 26 to space the second circuit card assembly 26 a predetermined distance from the first circuit card assembly 24.

The plurality of deflectable arms 36 may each include an outer surface 37 with an outwardly tapered section 38 that increases in distance from the longitudinal axis 30 as the outer surface 37 moves from the stopper wall 32 toward the tip 22, and an inwardly tapered section 40 that decreases in distance from the longitudinal axis 30 as the outer surface 37 moves from the outwardly tapered section 38 toward the tip 22. The inwardly tapered section 40 may engage the second attachment opening 27 in the second circuit card assembly 26 to couple the fastener 10 to the second circuit card assembly 26. The plurality of deflectable arms 36 may each include a chamfer 42 at the tip 22 on an internal edge of the deflectable arms 36 closest to the longitudinal axis 30. The plurality of deflectable arms 36 may include any operable number of deflectable arms 36, such as four deflectable arms 36, for example.

Referring to FIG. 2B, an insertion tool 50 may be used for inserting the fastener 10 of into the circuit card housing 11. The insertion tool 50 may include a body 52 defining a cavity 54 with a first internal section 56 having a first radius and a second internal section 58 having a second radius greater than the first radius, where the second internal section 58 is positioned between the first internal section 56 and an open end 57 of the cavity 54. The cavity 54 of the insertion tool 50 may further include a tapered section 59 between the first internal section 56 and the second internal section 58 for contacting and engaging an insertion section 46 of the second pin 16. The second pin 16 may include an insertion section 46 at an end of the pedestal 44 that the plurality of deflectable arms 36 extend from, where the insertion section 46 comprises a tapered surface 48.

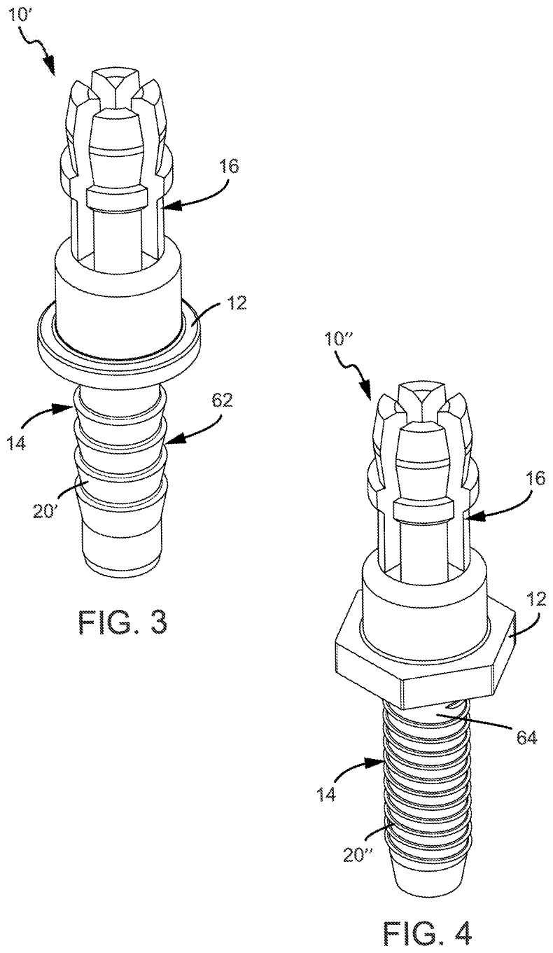

Now referring to FIG. 3, another embodiment of the fastener 10′ is depicted. The fastener 10′ may include each of the features described above with reference to FIG. 2A, except for the surface feature 20′. Accordingly, like features will not be described again for brevity. The surface feature 20′ of the fastener 10′ may be a plurality of barbs 62, where each of the plurality of barbs 62 circumferentially surrounds the longitudinal axis 30 and the plurality of barbs 62 are spaced apart along the longitudinal axis 30. The plurality of barbs 62 are arranged sequentially along the longitudinal axis 30. The plurality of barbs 62 may include any operable numbers of barbs, including 1, 20, or any number in between and, more specifically, 12 barbs. The barbs may each have a uniform thickness (e.g., distance along the longitudinal axis 30) and a uniform spacing between barbs along the longitudinal axis 30.

Referring now to FIG. 4, yet another embodiment of the fastener 10″ is depicted. The fastener 10″ may include each of the features described above with reference to FIGS. 2A and 3, except for the surface feature 20″. Accordingly, like features will not be described again for brevity. The surface feature 20 of the fastener 10 may be a threaded surface 64, similar to a screw or bolt, such that the fastener 10 may be screwed into the circuit card housing 11 to be coupled to the circuit card housing 11. In such embodiments, the head 12 of the fastener 10″ may be hexagonal or another shape that allows for a tool to grip the head 12 and rotate the fastener 10″.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A fastener for fastening circuit card assemblies, the fastener comprising:
a head having a first radius;
a first pin having a second radius smaller than the first radius, the first pin extends from the head along a longitudinal axis, the first pin comprising an outer surface circumferentially surrounding the longitudinal axis and a surface feature extending on the outer surface between the head and a tip of the pin, the surface feature is configured to engage a first circuit card assembly; and
a second pin extending from the head along the longitudinal axis in a direction opposite the first pin, the second pin comprising a stopper wall and a plurality of deflectable arms configured to deflect toward the longitudinal axis when inserted into a second circuit card assembly to couple the second pin to the second circuit card assembly, and the stopper wall extends from at least one of the plurality of deflectable arms away from the longitudinal axis, the stopper wall is configured to contact the second circuit card assembly when the plurality of deflectable arms are coupled to the second circuit card assembly.

2. The fastener of claim 1, wherein the plurality of deflectable arms each include an outer surface with an outwardly tapered section that increases in distance from the longitudinal axis as the outer surface moves from the stopper wall toward the tip, and an inwardly tapered section that decreases in distance from the longitudinal axis as the outer surface moves from the outwardly tapered section toward the tip.

3. The fastener of claim 1, wherein the plurality of deflectable arms each include a chamfer at the tip on an internal edge of the deflectable arms closest to the longitudinal axis.

4. The fastener of claim 1, wherein the plurality of deflectable arms comprises four deflectable arms.

5. The fastener of claim 1, wherein the stopper wall extends from each of the plurality of deflectable arms to radially circumscribe the longitudinal axis.

6. The fastener of claim 1, wherein the second pin further comprises a pedestal that the plurality of deflectable arms extend from.

7. The fastener of claim 6, wherein the pedestal comprises an insertion section at an end of the pedestal that the plurality of deflectable arms extend from, the insertion section comprises a tapered surface.

8. An insertion tool for inserting the fastener of claim 1, the insertion tool comprising a body defining a cavity with a first internal section having a first radius and a second internal section having a second radius greater than the first radius, and the second internal section is positioned between the first internal section and an open end of the cavity.

9. The fastener of claim 8, wherein the cavity of the insertion tool further comprises a tapered section between the first internal section and the second internal section for contacting and engaging an insertion section of the second pin, and the second pin comprises a pedestal that the plurality of deflectable arms extend from, and an insertion section at an end of the pedestal that the plurality of deflectable arms extend from, the insertion section comprises a tapered surface.

10. A fastener for fastening circuit card assemblies, the fastener comprising:
a head having a first radius;
a first pin having a second radius smaller than the first radius, the first pin extends from the head along a longitudinal axis, the first pin comprising an outer surface circumferentially surrounding the longitudinal axis and a surface feature extending on the outer surface from the head toward a tip of the pin, the surface feature comprises at least one of: a plurality of barbs, a helical knurl, and a plurality of threads, and the surface feature is configured to engage a first circuit card assembly; and
a second pin extending from the head along the longitudinal axis in a direction opposite the first pin, the second pin comprising a plurality of deflectable arms configured to deflect toward the longitudinal axis when inserted into a second circuit card assembly to couple the second pin to the second circuit card assembly.

11. The fastener of claim 10, wherein the plurality of deflectable arms each include an outer surface with an outwardly tapered section that increases in distance from the longitudinal axis as the outer surface moves from the stopper wall toward the tip, and an inwardly tapered section that decreases in distance from the longitudinal axis as the outer surface moves from the outwardly tapered section toward the tip.

12. The fastener of claim 10, wherein the plurality of deflectable arms comprises four deflectable arms.

13. The fastener of claim 10, wherein the stopper wall extends from each of the plurality of deflectable arms to radially circumscribe the longitudinal axis.

14. The fastener of claim 10, wherein the second pin further comprises a pedestal that the plurality of deflectable arms extend from.

15. The fastener of claim 14, wherein the pedestal comprises an insertion section at an end of the pedestal that the plurality of deflectable arms extend from, the insertion section comprises a tapered surface.

16. The fastener of claim 10, wherein the plurality of barbs are arranged sequentially along the longitudinal axis.

17. The fastener of claim 10, further comprising a chamfer at a tip of the pin that has an angle between 25° and 40° relative to the longitudinal axis.

18. The fastener of claim 10, further comprising a length of the pin that does not include the surface feature positioned between the surface feature and a tip of the pin.

19. The fastener of claim 10, wherein the surface feature is the plurality of barbs, and each of the plurality of barbs circumferentially surrounds the longitudinal axis, and the plurality of barbs are spaced apart along the longitudinal axis.

20. The fastener of claim 10, wherein the surface feature is the helical knurl having a plurality of knurls extending from the head to the tip of the pin, the plurality of knurls forming a helix wherein each of the plurality of knurls at least partially circumferentially surrounds the longitudinal axis.
